(19) United States
(12) Patent Application Publication
(10) Pub. No.: US 2005/0224888 A1
(43) Pub. Date: Oct. 13, 2005

(54) Integrated circuit array

(75) Inventors: Andrew Graham, Munich (DE); Franz Hofmann, Munich (DE); Wolfgang Honlein, Unterhaching (DE); Johannes Kretz, Munich (DE); Franz Kreupl, Munich (DE); Erhard Landgraf, Munich (DE); Richard J. Luyken, Munich (DE); Wolfgang Roesner, Ottobrunn (DE); Thomas Schulz, Austin, TX (US); Michael Specht, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/116,139

(22) Filed: Apr. 27, 2005

Related U.S. Application Data
(63) Continuation of application No. PCT/DE03/03612, filed on Oct. 30, 2003.

(30) Foreign Application Priority Data
Oct. 31, 2002 (DE) 102 50 830.5

(51) Int. Cl. H01L 29/76

(52) U.S. Cl. 257/368

(57) ABSTRACT

Integrated circuit array having field effect transistors (FETs) formed next to and/or above one another. The array has a substrate, a planarized first wiring plane with interconnects and first source/drain regions of the FETs, a planarized first insulator layer on the first wiring plane, a planarized gate region layer, which has patterned gate regions made of electrically conductive material and insulator material introduced therebetween, on the first insulated layer, a planarized second insulator layer on the gate region layer, holes formed through the second insulator layer, the gate regions, and the first insulator layer, a vertical nanoelement serving as a channel region in each of the holes, a second wiring plane with interconnects and second source/drain regions of the FETs, each nanoelement being arranged between the first and second wiring planes, and a gate insulating layer between the respective vertical nanoelement and the electrically conductive material of the gate regions.

### CROSS-REFERENCE TO RELATED APPLICATION

This application is a continuation of International Patent Application Serial No. PCT/DE2003/003612 filed on Oct. 30, 2003, which published in German on May 13, 2004 as WO 2004/040668, and is incorporated herein by reference in its entirety.

### FIELD OF THE INVENTION

The invention relates to a field effect transistor assembly and an integrated circuit array.

### BACKGROUND OF THE INVENTION

Conventional silicon microelectronics will encounter its limits as miniaturization advances further. One problem is that a MOS transistor cannot be miniaturized arbitrarily since, as miniaturization is continued, disturbing short channel effects, in particular, occur to an ever greater extent.

Furthermore, conventional silicon microelectronics are not well suited to a three-dimensional integration of integrated components, i.e., clearly stacking layers of components (e.g., planes of memory elements).

DE 100 36 897 C1 discloses introducing a passage hole into a gate electrode layer of a layer sequence set up as a field effect transistor and growing a vertical nanoelement in the passage hole. This affords a vertical field effect transistor with the nanoelement as channel region, the electrical conductivity of the channel region being controllable by means of the gate electrode region surrounding the nanoelement along approximately its entire longitudinal extent. In the case of the field effect transistor disclosed in DE 100 36 897 C1, the nanotube is arranged between two simple electrodes as source/drain regions, the arrangement having an intense surface topology, i.e., not being planar, which can make it more difficult to realize a 3D integration and the construction of more complex circuits.

Zhou, C., Kong, J., Yenilmez, E., Dai, H. (2000) “Modulated Chemical Doping of Individual Carbon Nanotubes” Science 290:1552, discloses that semiconducting carbon nanotubes which have a conductivity of the p conduction type after growth on a substrate can be converted to the n conduction type by introducing potassium material in the carbon nanotubes.

### SUMMARY OF THE INVENTION

The invention is based on the problem of providing a field effect transistor assembly and an integrated circuit array which are suitable even for more complex circuitry applications.

A field effect transistor assembly according to the invention contains a substrate, a first wiring plane with a first source/drain region on the substrate, and a second wiring plane with a second source/drain region above the first wiring plane. At least one vertical nanoelement as channel region is arranged between the wiring planes and coupled to both of the latter. Furthermore, electrically conductive material that at least partially surrounds the nanoelement is provided as gate region and electrically insulating material is provided as gate insulating layer between the nanoelement and the electrically conductive material.

The integrated circuit array according to the invention has a plurality of field effect transistor arrangements having the features described above formed one beside the other and/or one above the other.

### BRIEF DESCRIPTION OF THE DRAWINGS

Exemplary embodiments of the invention are illustrated in the figures and are explained in more detail below.

In the figures:

FIGS. 1 to 3 show layer sequences at different points in time during a method for fabricating a field effect transistor assembly in accordance with a first exemplary embodiment of the invention;

FIG. 4 shows a field effect transistor assembly in accordance with a first exemplary embodiment of the invention;

FIG. 5 shows an equivalent circuit diagram of a partial region of the field effect transistor assembly shown in FIG. 5, set up as an inverter circuit;

FIG. 6 shows a plan view of a field effect transistor assembly in accordance with a second exemplary embodiment of the invention;

FIG. 7 shows a cross-sectional view of the field effect transistor assembly shown in FIG. 6, taken along a section line I-I′;

FIG. 8 shows a cross-sectional view of the field effect transistor assembly shown in FIG. 6, taken along a section line II-II′; and

FIG. 9 shows a field effect transistor assembly in accordance with a third exemplary embodiment of the invention.

### DETAILED DESCRIPTION OF PREFERRED EMBODIMENTS OF THE INVENTION

Identical or similar components in different figures are provided with identical reference numerals.

In the field effect transistor assembly according to an embodiment of the invention, a field effect transistor is formed between two wiring planes, that is to say between two metallization planes that are patterned in a suitable manner relative to a specific application. The wiring planes make it possible for the field effect transistor to be coupled or to be connected to other circuitry components flexibly relative to the application of the individual case. The structure of the field effect transistor assembly has a high degree of planarity, that is to say a modular arrangement of preferably planar planes arranged one above the other (substrate, first wiring plane, active component or coupling plane, second wiring plane). This ensures a simple, modular fabrication method. This makes it possible to construct complex integrated circuits with different, interconnected components such as, for example, memory cells, transistors and logic components. In contrast to DE 100 36 897 C1 the field effect transistor assembly according to the invention is not provided with simple electrodes as first and second source/drain region, the source/drain regions are instead set up as partial regions of complex metallization or wiring planes, thereby enabling coupling to other integrated components with a low outlay. Consequently, it is possible to form a complex integrated circuit comprising different components (e.g., memory cells and logic components).

One aspect of the invention can clearly be seen in the fact that an active component plane with the vertical nanoelement (i.e., a plane that can be ascribed to the front end of processing) is formed between two suitably patterned and in each case not necessarily contiguous wiring planes (i.e., two planes that can be ascribed to the back end of processing). Such an interleaving of front-end and back-end components results from the idea of connecting up vertical and thus space-saving field effect transistors, for which purpose, clearly, contact-connections are formed as partial regions of the wiring planes above and below the field effect transistors. If a field effect transistor is intended to be embedded in a more complex circuitry environment, a realization of the source/drain regions as components of the wiring planes is a better solution than the isolated provision of separate source/drain regions for each individual field effect transistor.

Using a vertical nanoelement as a component of the field effect transistor assembly achieves a high degree of miniaturization, and disturbing short channel effects are avoided at the same time. Clearly, the length of the channel region of the field effect transistor assembly is predetermined by means of the length of the nanoelement, so that the nanoelement can be made long enough for the purpose of avoiding disturbing short channel effects and, at the same time, an increase in the lateral space requirement is avoided on account of the vertical arrangement.

On account of the planar arrangement, the field effect transistor assembly of the invention is well suited to a 3D integration, that is to say to a system comprising a plurality of component layers formed one on top of the other. The integration density is increased further as a result.

Clearly, the field effect transistor assembly according to the invention has at least two interconnect planes between which nanoelement transistors are arranged. In the case of this active component, the gate region is formed from a region of the electrically conductive material, which preferably has vertical pores in which the at least one nanoelement of a respective transistor channel is arranged.

It should be noted that different nanoelements of the field effect transistor assembly can be assigned to different field effect transistors; in other words, the field effect transistor assembly according to the invention is not restricted to an individual field effect transistor, but rather may contain a plurality of field effect transistors using common first and second wiring planes.

One important aspect of the invention can be seen in the fact that a vertical field effect transistor is embedded in an overall arrangement that is simple to fabricate.

The electrically conductive material is preferably an electrically conductive layer into which is introduced at least one vertical passage hole through which the nanoelement is led. The realization of the electrically conductive material as an electrically conductive layer with a vertical passage hole introduced therein supports the planar character of the field effect transistor assembly according to the invention. By means of a lithography and etching method that is not very complex, one or a plurality of passage holes can be introduced at targeted locations of the electrically conductive layer, thereby creating a simple nanoelement circuit architecture.

At least one electrically insulating layer with at least one vertical passage hole through which the nanoelement is led may be arranged between the first and second wiring planes. The use of electrically insulating layers as components of the preferably completely planar field effect transistor assembly also underlines the modular or layered construction of the field effect transistor assembly. The electrically insulating layer may be provided for electrically decoupling the wiring planes from one another. Preferably, a shared lithography and etching method may be used for patterning the electrically conductive layer and the electrically insulating layer, thereby further reducing the fabrication outlay.

The substrate may be an amorphous or polycrystalline substrate. One advantage of the invention can be seen in the fact that the field effect transistor assembly according to the invention can be realized with an arbitrary substrate, so that an expensive monocrystalline substrate (such as a silicon wafer for example) is dispensable, thereby reducing the fabrication costs. A cost-effective amorphous or polycrystalline substrate is entirely sufficient for the needs of the field effect transistor assembly. Applying the different components on the substrate in a layered manner enables a 3D integration in a simple manner. Consequently, a plurality of planes of active components can be arranged one above the other.

The field effect transistor assembly according to the invention may consist of dielectric material, metallically conductive material and the material of the nanostructure. One essential idea of the invention can thus be seen in fabricating an electronic circuit with a vertical field effect transistor only from electrical conductor material, dielectric material and nanoelements. This creates a particularly cost-effective technology in which the use of expensive semiconductor material is avoided.

The substrate may be, by way of example, a glass substrate, a quartz substrate, a sapphire substrate, a silicon oxide substrate, a plastic substrate, a ceramic substrate, a polycrystalline semiconductor substrate. It is possible to use almost any cost-effective substrate for forming the field effect transistor assembly. For integrating components of silicon microtechnology into a substrate, it may be advantageous to use a crystalline semiconductor substrate, for example a silicon wafer.

Furthermore, it should be noted that the substrate used may also be, in particular, a mechanically flexible substrate (for example made of an organic material).

The nanoelement may have a nanotube, a bundle of nanotubes or a nanorod. The nanorod may be formed for example from silicon, germanium, indium phosphide, gallium nitride, gallium arsenide, zirconium oxide and/or a metal. A nanoelement configured as a nanotube may be a carbon nanotube, a carbon-boron nanotube, a carbon-nitrogen nanotube, a tungsten sulfide nanotube or a chalcogenide nanotube.

In particular, at least one of the at least one nanoelement may be of the n conduction type. In the context of forming a carbon nanotube as an important example of a nanoelement, the dictates of fabrication mean that a carbon nanotube of the p conduction type is often obtained. For many applications, for example a p-MOSFET or a diode with a pn junction, it may be desirable for at least one part of a nanotube to be of the n conduction type. By introducing potassium material into a p-conducting carbon nanotube, it is possible for a carbon nanotube that is obtained in p-conducting fashion after growth to be converted into an n-conducting state. By way of example, a p-conducting nanotube may be grown in a passage hole whose surrounding material contains potassium. By means of thermal drive-out of potassium material from the surrounding solid, potassium material can be introduced into the nanostructure, as a result of which a p-doped carbon nanotube can be converted into an n-doped carbon nanotube.

The field effect transistor assembly according to the invention may also be set up as a nonvolatile memory cell, the electrically insulating material serving as a storage layer for electrical charge carriers and being set up in such a way that electrical charge carriers can be selectively introduced therein or removed therefrom. Furthermore, the electrical conductivity of the nanoelement can be characteristically influenced by means of electrical charge carriers introduced in the electrically insulating material. Clearly, the gate insulating layer may be formed from a material such that, by means of applying suitable electrical potentials to the source/drain regions or the gate region of the field effect transistor, electrical charge carriers can be permanently injected into the gate insulation layer for example by means of Fowler-Nordheim tunneling or by means of the tunneling of hot electrons/holes. On account of the field effect, the permanently introduced electrical charge carriers bring about a shift in the threshold voltage of the field effect transistor, in which a memory information item can be coded. Examples of suitable material for the electrically insulating material as charge store are a silicon oxide-silicon nitride-silicon oxide layer sequence (ONO layer sequence) or an aluminum oxide layer. In such a case, the field effect transistor assembly can be used as a permanent memory cell or permanent memory cell assembly.

As an alternative, the field effect transistor assembly may be set up as a DRAM memory cell (“dynamic random access memory”), it being possible for the field effect transistor to be set up as a switching transistor and for a stacked capacitor to be provided as storage capacitor, the nanoelement being grown on at least one part of the storage capacitor. The realization of the field effect transistor assembly as a DRAM memory cell is promoted by means of the layered construction since the formation of a stacked capacitor can be conveniently integrated into the layered architecture.

The field effect transistor assembly according to the invention may furthermore be set up as a CMOS component, two field effect transistors being formed in the manner described above, of which one has a nanoelement of the p conduction type and the other has a nanoelement of the n conduction type. The field effect transistor assembly according to the invention can thus be tailored to the requirements of the CMOS technology, the space requirement of a CMOS component being considerably reduced on account of the use of vertical nanotubes in comparison with conventional CMOS technology. The field effect transistor assembly according to the invention makes it possible to integrate all the required constituent parts of a CMOS circuit with a low outlay.

Preferably, the field effect transistors of the CMOS component may be connected to form an inverter circuit, which, when a logic signal is applied to an input, converts the signal into a logic signal at an output which has a logically complementary value relative to the signal at an input.

At least one of the at least one passage hole may be filled with electrically conductive coupling material for coupling the first and second wiring planes.

In the case of a more complex field effect transistor assembly which has further components in addition to the field effect transistor or in which different terminals of the field effect transistor are coupled to one another, passage holes (vias) through one or more layers of the arrangement may be advantageous, which may be realized by means of electrically conductive material introduced into the passage holes between the wiring planes. In particular, the electrically conductive coupling material may be a bundle of nanoelements which has a sufficiently good electrical conductivity. Using a bundle of nanoelements as coupling means for filling a passage hole makes it possible to obtain a coupling element having extremely small dimensions (namely in the region of a few nanometers or less).

The field effect transistor arrangement is preferably set up as a layer sequence comprising a plurality of planarized layers. In other words, the field effect transistor assembly is preferably constructed in completely planar fashion, that is to say that the interconnect planes as well as the gate electrodes are arranged on an in each case essentially planar support without a pronounced topology and the interspaces within these planes are filled with dielectric material, so that the surface of this layer is in turn planar. A dielectric layer permeated by the nanoelements and by the contact holes may in each case be arranged between the interconnect planes and a gate plane. The realization of a completely planar construction can be supported by carrying out a planarization method step after the formation of a respective plane, in order to realize a planar surface. This may be realized particularly advantageously using the CMP method (“chemical mechanical polishing”). The extension of the planar arrangement to a three-dimensional integration results for example through multiple repetition of the process sequence, i.e., repeated deposition of layer sequences one on top of the other.

Moreover, the electrically insulating material surrounding the nanoelement may be realized as a ring structure which forms the gate insulating layer of the vertical transistor, and at least one part of the electrically insulating ring structure may be surrounded by the electrically conductive material which forms the gate electrode of the vertical transistor.

By virtue of the fact that the nanoelement is surrounded by an electrically insulating ring structure (instead of by a structure like the outer surface of a cylinder), a gate insulating layer is provided which is surrounded by the electrically conductive material functioning as gate electrode. The conductivity of the nanoelement, functioning as channel region, can be characteristically influenced by applying a suitable voltage to the electrically conductive material, so that the nanoelement together with the electrically insulating ring structure and the electrically conductive material fulfils the functionality of a field effect transistor having particularly high sensitivity. By means of using an annular gate electrode, it is possible, on account of an electrostatic tip effect, for the amplitude of an electric field generated by applying an electrical voltage to the gate electrode to be made particularly large near the nanoelement, thereby enabling a particularly exact control of the electrical conductivity of the channel region.

One important aspect of the integrated circuit architecture according to the invention is to provide an integrated circuit having a plurality of different components which are connected to one another.

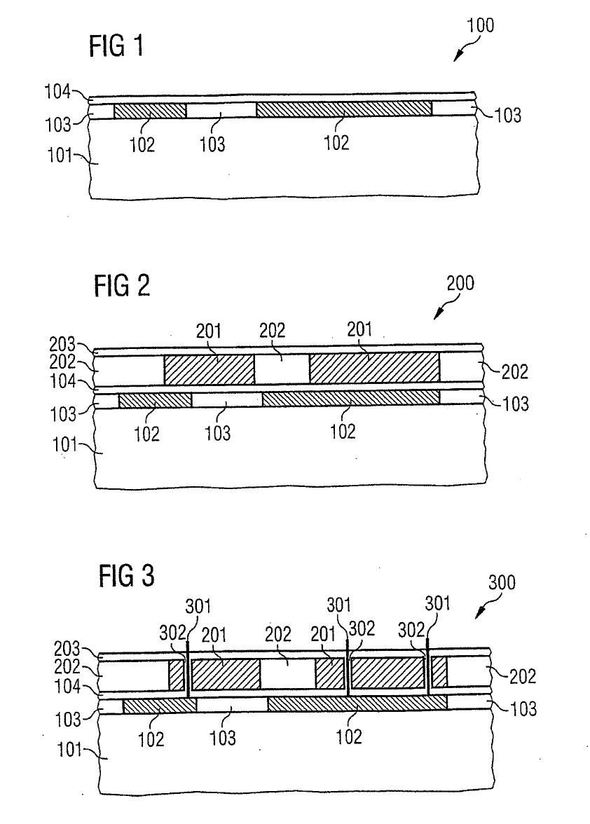

A description is given below, referring to FIG. 1 to FIG. 4, of a method for fabricating a field effect transistor assembly in accordance with a first exemplary embodiment of the invention.

In order to obtain the layer sequence 100 shown in FIG. 1, a nickel layer is deposited on a glass substrate 101 and patterned using a lithography and an etching method, as a result of which a first nickel wiring plane 102 is obtained. In a further method step, aluminum oxide (Al₂O₃) is deposited with a sufficient thickness on the layer sequence thus obtained and planarized using a CMP method (“chemical mechanical polishing”) with the nickel material of the first nickel wiring plane 102 as a stop layer. The aluminum oxide material that remains between the components of the first nickel wiring plane 102 forms a first aluminum oxide structure 103. The components 102, 103 together form a fully planar layer. A first aluminum oxide layer 104 is deposited on the layer sequence thus obtained.

In order to obtain the layer sequence 200 shown in FIG. 2, aluminum material is deposited on the layer sequence 100 and patterned using a lithography and an etching method in such a way that gate regions 201 remain for field effect transistors that are subsequently to be formed. Furthermore, aluminum oxide material is deposited with a sufficient thickness on the layer sequence thus obtained and planarized using a CMP method with the aluminum material of the gate regions 201 as a stop layer. This results in a second aluminum oxide structure 202, which, together with the gate regions 201, forms a further planar layer. Afterward, aluminum oxide material is deposited on the layer sequence thus obtained, as a result of which a second aluminum oxide layer 203 is produced. It should be noted that the gate regions 201 and the second aluminum oxide structure 202 together form a further fully planar plane, which plane is isolated from the plane formed from the components 102, 103 by means of the first aluminum oxide layer 104. The second aluminum oxide layer 203 arranged on the surface of the layer sequence 200 is likewise planar.

In order to obtain the layer sequence 300 shown in FIG. 3, a pore mask is produced on the surface of the layer sequence 200 using an electron beam lithography method, which pore mask is used to define the locations of a later growth of carbon nanotubes. In a further method step, using a suitable etching method in accordance with the pore mask formed, firstly aluminum oxide material of the second aluminum oxide layer 203, then aluminum material of the gate regions 201 and finally aluminum oxide material of the first aluminum oxide layer 104 are removed. As a result, passage holes are etched at defined locations in the layers 104, 202 and 203 arranged one on top of the other. The aluminum material of the gate regions 201 that is uncovered at the surfaces of the passage holes is oxidized at the surface by means of thermal oxidation with a thickness in the nanometers range, thereby forming a gate insulating layer 302 made of aluminum oxide material for the later field effect transistors. In a further method step, using a CVD method (“chemical vapor deposition”) semiconducting carbon nanotubes 301 are grown on the nickel material, which catalytically supports the growth of carbon nanotubes 301, the passage holes through the layers 104, 202, 203 clearly serving as stencils for the growth of the carbon nanotubes 301. As an alternative to the nickel material, iron or cobalt, for example, can be used as catalyst material. By means of the passage holes, a defined growth direction is prescribed for the carbon nanotubes 301, so that structurally well-defined vertical carbon nanotubes 301 are obtained.

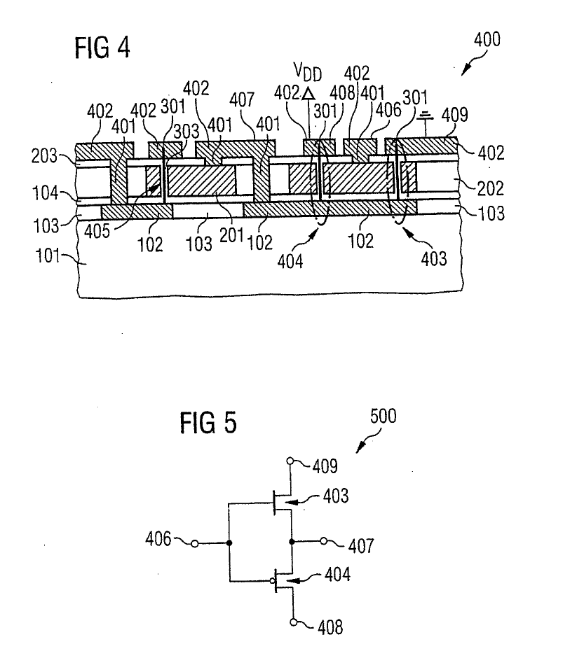

In order to obtain the field effect transistor assembly 400 in accordance with a first exemplary embodiment of the invention as shown in FIG. 4, contact holes are etched into the layer sequence 300 by means of a lithography and an etching method using nickel material of the first nickel wiring plane 102 and aluminum material of the aluminum gate regions 201 as stop material. The contact holes are filled by deposition of nickel material, thereby forming vertical nickel coupling elements 401. By depositing additional nickel material, a nickel layer is formed on the surface of the layer sequence thus obtained, and is patterned using a lithography and an etching method in such a way that a second nickel wiring plane 402 is generated.

The field effect transistor assembly 400 clearly represents a planar layer arrangement formed from layer planes applied one on top of the other, formed from a first plane 102, 103, a second plane 201, 202 and a third plane 402. The coupling between different planes is realized by means of vertical coupling elements 301, 401. As a result, a novel circuit architecture on the basis of nanoelements is created, in the case of which a surface topology which constitutes a disturbance for 3D integration is avoided.

Clearly, the field effect transistor assembly 400 contains a first field effect transistor 403, a second field effect transistor 404 and a third field effect transistor 405. In the case of the first field effect transistor 403, the carbon nanotube 301 forms the channel region, a boundary region between the carbon nanotube 301 and the first nickel wiring plane 102 forms a first source/drain region of the first field effect transistor 403, a boundary region between the carbon nanotube 301 and the second nickel wiring plane 402 forms a second source/drain region, the aluminum material surrounding the carbon nanotube 301 forms the gate region 201 of the first field effect transistor 401, and the thermally oxidized aluminum oxide material at the wall of the passage hole introduced into the gate region 201 forms the gate insulating layer 302 of the first field effect transistor 403. The second and third field effect transistors 404, 405 are formed in a similar manner to the first field effect transistor 403.

A description is given below of how the field effect transistor assembly 400 is set up, connected up and operated as a CMOS inverter.

It should be noted that, for a use of the field effect transistors 403, 404 as an inverter, the first field effect transistor 403 is of the n conduction type, whereas the second field effect transistor 404 is of the p conduction type. In order to realize this, it is possible, by way of example, for the first field effect transistor 403 to be formed in a different method step than the second field effect transistor 404, the conduction type (n-type or p-type conduction) of the respective carbon nanotube 301 being set by means of setting the reaction parameters during the CVD method for depositing the carbon nanotubes 301 of the n-MOS field effect transistor 403 and of the p-MOS field effect transistor 404. As an alternative, in a manner similar to that described in Zhou et al., the n-MOS field effect transistor 403 can be formed by virtue of the material of the gate region 201 that surrounds it being provided with potassium material, and this potassium material being driven out thermally from the gate region 201, as a result of which the potassium material is injected as dopant into the carbon nanotube 301 of the n-MOS field effect transistor 403. If the p-conducting carbon nanotube 301 of the p-MOS field effect transistor 404 is not formed until afterward, then an n-MOS field effect transistor 403 and a p-MOS field effect transistor 404 are realized as a basis for a CMOS-like component.

A description is given below of how the field effect transistor assembly 400 can be operated as an inverter circuit. An input signal that is to be processed in accordance with the inverter logic can be applied to an inverter input 406, which is realized as a component of the second nickel wiring plane 402. An output signal is provided at an inverter output 407 as terminal of a different component of the second nickel wiring plane 402, which output signal is generated from the input signal, provided at the inverter input 406, on account of the functionality of the field effect transistors 403, 404, connected up in the manner shown in FIG. 4, in accordance with the inverter logic. A supply voltage VDD is applied to a supply voltage terminal 408 of the second nickel wiring plane 402. Clearly, the supply voltage terminal 408 is coupled to the second source/drain terminal of the second field effect transistor 404. Furthermore, the electrical ground potential can be applied to a ground potential terminal 409 as a different component of the second nickel wiring plane 402. The second source/drain terminal of the first field effect transistor 403 is thus at electrical ground potential. The first source/drain terminals of the field effect transistors 403, 404 are coupled to one another by means of a component of the first nickel wiring plane 102.

It should be noted that both the first nickel wiring plane 102 and the second nickel plane 402 in each case contain a plurality of non-contiguous components that are electrically decoupled from one another in part, as a result of which the functionality striven for in the field effect transistor assembly according to the invention is achieved in the first place.

FIG. 5 shows an equivalent circuit diagram 500 of the field effect transistors 403, 404 connected up in the manner shown in FIG. 4. In accordance with the inverter logic of the field effect transistor assembly 400 connected up as an inverter circuit, a signal having a logic value “0” is provided at the inverter output 407 precisely when the input signal 406 is at a logic value “1”. A signal having a logic value “1” is provided at the inverter output 407 precisely when the input signal 406 is at a logic value “0”.

The two field effect transistors 403, 404 form an inverter with an n-channel transistor 403 and a p-channel transistor 404. The respective second source/drain regions are at the ground potential 409 and the potential of the supply voltage VDD 408, respectively, the gate region 201 is provided jointly for the two transistors 403, 404 and is coupled to the inverter input 406. The second source/drain regions of the transistors 403, 404 are coupled to one another and form the inverter output 407.

On account of the coupling shown in FIG. 4, the gate region 201 of the third field effect transistor 405 can be driven by means of the electrical potential present at the inverter output 407. Consequently, the simple inverter functionality of the transistors 403, 404 is extended by means of the third field effect transistor 405, thereby realizing a more complex CMOS circuit.

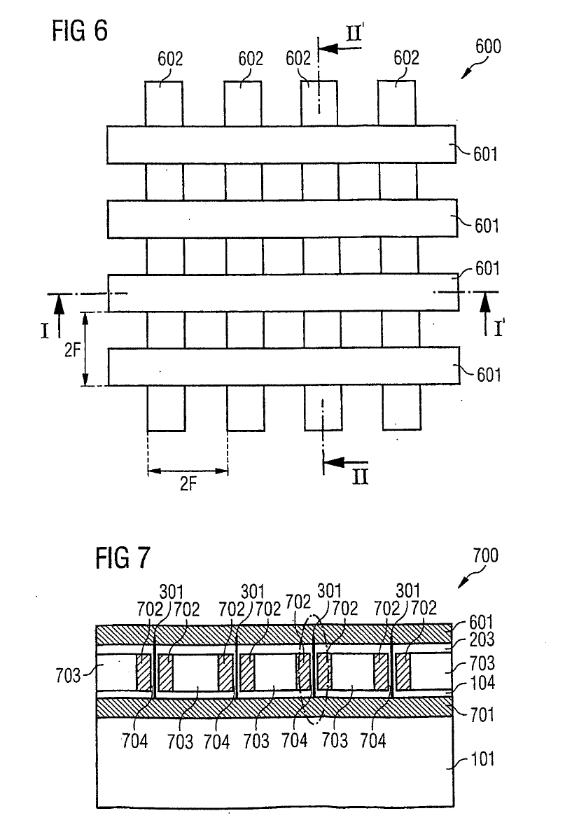

A description is given below, referring to FIG. 6 to FIG. 8, of a field effect transistor assembly 600 in accordance with a second exemplary embodiment of the invention.

FIG. 6 shows a plan view of the field effect transistor assembly 600, which field effect transistor assembly 600 is realized as a nonvolatile memory cell arrangement. FIG. 6 shows a multiplicity of first bit lines 601 which run along a first direction and are arranged such that they run above a multiplicity of word lines 602 running along a second direction, which is orthogonal to the first direction. Clearly, a memory cell is formed in each crossover region between one of the word lines 602 and one of the first bit lines 601.

FIG. 6 reveals that the distance between two mutually adjacent first bit lines 601 or two mutually adjacent word lines 602 is 2F in each case, where F is the minimum feature dimension that can be achieved in a technology generation. Consequently, the space requirement of a memory cell is 4F², so that a particularly high integration density is achieved.

A description is given below, referring to FIG. 7, of a first cross-sectional view 700 of the field effect transistor assembly 600, taken along a section line I-I′ shown in FIG. 6.

The first cross-sectional view 700 shows the vertical layer construction of the field effect transistor assembly 600 formed as a nonvolatile memory cell arrangement in NOR architecture. Second bit lines 701 made of nickel material which run parallel to one another are formed on a glass substrate 101, only one of which bit lines is shown in FIG. 7 on account of the sectional view. The second bit lines 701 are formed by a continuous nickel layer firstly being deposited on the glass substrate 101 and then being patterned using a lithography and an etching method to form second bit lines 701 which run parallel to one another. In other words, the second bit lines 701 run essentially parallel to the first bit lines 601. After the patterning method, the interspaces between the second bit lines 701 are filled with electrically insulating material, and the layer sequence thus obtained is planarized using a CMP method. As an alternative, the second bit lines 701 may be formed using a damascene method.

A first aluminum oxide layer 104 is deposited on the layer sequence thus obtained. An aluminum layer is deposited on the layer sequence thus obtained and patterned using a lithography and an etching method in such a way that gate regions 702 remain. The latter are arranged in such a way that a separate gate region 702 is created for each field effect transistor that is subsequently formed. The interspaces between adjacent gate regions 702 are filled with an aluminum oxide structure 703. The layer sequence thus obtained is planarized using a CMP method. A second aluminum oxide layer 203 is then deposited. In a manner similar to that shown in FIG. 3, a pore mask is produced using an electron beam lithography method, which pore mask is used to define the later growth locations of carbon nanotubes. Using an etching method, the second aluminum oxide layer 203, the gate regions 702 and the first aluminum oxide layer 104 are then etched for the purpose of generating passage holes, as a result of which surface regions of the first nickel bit line 701 are uncovered. An uncovered surface region of the aluminum material of the gate regions 702 in the passage holes is thermally oxidized, thereby producing a hollow-cylindrical aluminum oxide layer as gate insulating layer 704 and as charge storage layer in each of the passage holes. By means of a CVD method, carbon nanotubes 301 are grown vertically on the uncovered surface regions of the second nickel bit line 701, which also serves as catalyst material for the growth of carbon nanotubes, the passage holes in the layers 104, 702 and 203 serving as a mechanical guide for the vertical growth of the carbon nanotubes 301. Further nickel material is deposited on the layer sequence thus obtained and is patterned, thereby generating the first bit lines 601 in the manner shown in FIG. 6.

As shown in FIG. 7, a multiplicity of field effect transistors are produced, first and second source/drain regions being formed by means of the coupling regions between the respective first and second bit lines 601, 701 and a respective carbon nanotube 301. A respective carbon nanotube 301 itself forms the channel region of the respective field effect transistor. The gate insulating charge storage layer 704 surrounding a respective carbon nanotube 301 fulfils the functionality of a gate insulating layer of the respective field effect transistor and furthermore fulfils the functionality of a charge storage layer. On account of the functionality as charge storage layer, it is set up in such a way that electrical charge carriers can be selectively introduced therein or removed therefrom, it being possible for the electrical conductivity of the carbon nanotubes 301 to be characteristically influenced by the electrical charge carriers introduced in the electrically insulating material. The gate regions 702 form a partial region of the word lines 602.

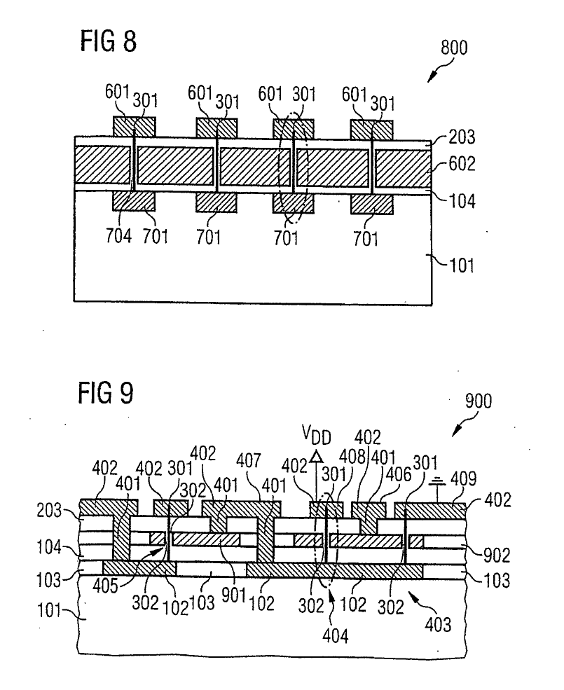

A description is given below, referring to FIG. 8 of a second cross-sectional view 800 of the field effect transistor assembly 600 set up as a permanent memory cell arrangement. The second cross-sectional view 800 is taken along a section line II-II′ shown in FIG. 6.

As shown in FIG. 8, the first and second bit lines 601, 701 run parallel to one another whereas the word lines 602 run orthogonally to the bit lines 601, 701. As is furthermore shown in FIG. 8, the four memory cells shown in FIG. 8 share a common word line 602. By contrast, the four memory cells shown in FIG. 7 share common first and second bit lines 601, 701.

The field effect transistor assembly 600 represents a nonvolatile memory cell arrangement in NOR architecture. FIG. 6 shows the layout of the arrangement, FIG. 7 shows a first cross-sectional view 700 along a bit line pair 601, 701 and FIG. 8 shows a second cross-sectional view 800 along a word line 602. A respective memory cell is situated in a crossover region between a bit line pair 601, 701, on the one hand, and a word line 602, on the other hand.

A gate dielectric made of aluminum oxide is provided in each of the memory cells; electrical charge carriers can be introduced and permanently stored in the gate dielectric, for example by means of Fowler Nordheim tunneling. On account of the very simple planar construction of the field effect transistor arrangement 600, an area requirement of 4F² results for each memory cell. The field effect transistor assembly 600 is suitable for a 3D integration. In other words, the layer sequences shown in FIG. 7, FIG. 8 can be multiply stacked one on top of the other in order to increase the integration density.

If electrical charge carriers are injected into the gate insulating layer of a respective memory cell, then the threshold voltage of the respective field effect transistor is thereby shifted, wherein a for example binary information item can be permanently stored. If a voltage is applied to a word line 602, then a row of memory cells can thereby be selected. If a voltage is applied between the bit lines 601, 701 associated with a memory cell, the value of the electric current is a measure of what memory information is stored in the respective memory cell, that is to say how many charge carriers and charge carriers of what charge type are contained in the gate insulating layer of the respective memory field effect transistor.

A description is given below, referring to FIG. 9, of a field effect transistor assembly 900 in accordance with a third exemplary embodiment of the invention.

The field effect transistor assembly 900 shown in FIG. 9 greatly resembles the field effect transistor assembly 400 shown in FIG. 4 with regard to construction and functionality.

The essential difference from the field effect transistor assembly 400 is that, in the case of the field effect transistor assembly 900, the electrically insulating material surrounding the carbon nanotubes 301 is clearly realized at a ring structure which forms the gate insulating layer 302 of the respective vertical transistor 402 to 405. Furthermore, the electrically insulating ring structure is surrounded by electrically conductive material of gate regions 901, which forms the gate electrode of the vertical transistors 403 to 405.

Clearly, the difference between the field effect transistor arrangements 400 and 900 can be seen in the fact that the second aluminum oxide structure 902 is a layer having a significantly smaller thickness than the second aluminum oxide structure 202, and that the gate regions 901 are realized as a layer having a significantly smaller thickness than the gate regions 201. By contrast, in FIG. 9 the thicknesses of the layers 104 and 203 are chosen to be larger than in accordance with FIG. 4.

By virtue of the fact that the carbon nanotubes 301 are surrounded by an electrically insulating ring structure, a gate insulating layer is provided which is surrounded by the electrically conductive material 901 functioning as gate electrode. By applying a suitable voltage to the electrically conductive material 901, the conductivity of the carbon nanotubes 301, functioning as channel region, can be influenced particularly sensitively on account of an electrostatic tip effect (as a consequence of the small thickness of the layer 901).

1. An integrated circuit array having field effect transistors formed next to and/or above one another, comprising:
a substrate;
a planarized first wiring plane with interconnects and first source/drain regions of the field effect transistors;
a planarized first insulator layer on the planarized first wiring plane;
a planarized gate region layer, which has patterned gate regions made of electrically conductive material and insulator material introduced therebetween, on the planarized first insulator layer;
a planarized second insulator layer on the planarized gate region layer;
a plurality of holes formed through the planarized second insulator layer, the gate regions, and the planarized first insulator layer;
at least one vertical nanoelement serving as a channel region in each of the holes;
a second wiring plane with interconnects and second source/drain regions of the field effect transistors;
the at least one nanoelement being arranged between the first wiring plane and the second wiring plane; and
electrically insulating material used as a gate insulating layer between the at least one vertical nanoelement and the electrically conductive material of the gate regions.

2. The integrated circuit array of claim 1, wherein the electrically insulating material of the gate insulating layer between the respective vertical nanoelement and the respective electrically conductive material of the gate region is an oxide of the electrically conductive material of the gate region.

3. The integrated circuit array of claim 2, wherein the oxide is a thermal oxide.

4. The integrated circuit array of claim 1, wherein the substrate is an amorphous substrate or a polycrystalline substrate.

5. The integrated circuit array of claim 1, further comprising dielectric material, metallically conductive material, and the material of the nanostructure.

6. The integrated circuit array of claim 1, wherein the substrate is a glass substrate, a quartz substrate, a sapphire substrate, a silicon oxide substrate, a plastic substrate, a ceramic substrate, or a polycrystalline semiconductor substrate.

7. The integrated circuit array of claim 1, wherein the nanoelement has a nanotube, a bundle of nanotubes, or a nanorod.

8. The integrated circuit array of claim 7, wherein the nanorod has silicon, germanium, indium phosphide, gallium nitride, gallium arsenide, zirconium oxide, or a metal.

9. The integrated circuit array of claim 7, wherein the nanotube is a carbon nanotube, a carbon-boron nanotube, a carbon-nitrogen nanotube, a tungsten sulfide nanotube, or a chalcogenide nanotube.

10. The integrated circuit array of claim 1, wherein the at least one nanoelement is of the n conduction type.

11. The integrated circuit array of claim 10, wherein the nanoelement of the n conduction type has potassium.

12. The integrated circuit array of claim 1, set up as a nonvolatile memory cell, the electrically insulating material serving as charge storage layer and being set up such that electrical charge carriers can be selectively introduced therein or removed therefrom, and the electrical conductivity of the nanoelement can be characteristically influenced by the electrical charge carriers.

13. The integrated circuit array of claim 12, wherein the electrically insulating material is a silicon oxide-silicon nitride-silicon oxide, layer sequence, or an aluminum oxide layer.

14. The integrated circuit array of claim 1, set up as a DRAM memory cell, wherein at least one of the field effect transistors is set up as a switching transistor, and
further comprising a stacked capacitor as a storage capacitor, the at least one nanoelement being grown on at least one part of the storage capacitor.

15. The integrated circuit array of claim 1, further comprising at least one CMOS component, wherein one field effect transistor has a nanoelement of the p conduction type and another field effect transistor has a nanoelement of the n conduction type.

16. The integrated circuit array of claim 15, wherein at least some of the field effect transistors are connected to form an inverter circuit.

17. The integrated semiconductor array of claim 1, further comprising additional holes formed through the planarized second insulator layer, the insulator material of the gate region layer, and the planarized first insulator layer, the additional holes being filled with an electrically conductive coupling material for electrically coupling the first wiring plane and the second wiring plane.

18. The integrated circuit array of claim 17, wherein the electrically conductive coupling material is a bundle of electrically conductive nanoelements.

19. The integrated circuit array of claim 1, wherein the electrically insulating material surrounding the at least one vertical nanoelement is realized as a ring structure, and
wherein at least one part of the electrically insulating ring structure is surrounded by the electrically conductive material.

20. A method for fabricating a circuit array having field effect transistors formed next to and/or above one another, comprising the steps of:
forming and planarizing a first wiring plane with interconnects and first source/drain regions of the field effect transistors;
forming and planarizing a first insulation layer on the planarized first wiring plane;
forming and planarizing a gate region layer on the first insulator layer, the gate region layer having patterned gate regions made of electrically conductive material and insulator material introduced therebetween;
forming and planarizing a second insulator layer on the planarized gate region layer;
forming holes through the planarized second insulator layer, the gate regions, and the planarized first insulator layer;
forming at least one vertical nanoelement, which serves as a channel region, in each of the holes;
forming electrically insulating material as gate insulating layer between the at least one vertical nanoelement and the electrically conductive material of the gate region; and
forming a second wiring plane with interconnects and second source/drain regions of the field effect transistors on the planarized second insulator layer, so that each nanoelement is arranged between the first wiring plane and the second wiring plane.

21. The method of claim 20, wherein the array is set up as a nonvolatile memory cell, the method further comprising the step of selectively introducing into or removing electrical charge carriers from the electrically insulating material, which serves as charge storage layer, wherein the electrical conductivity of the nanoelement is characteristically influenced by the electrical charge carriers.

22. A system for fabricating a circuit array having field effect transistors formed next to and/or above one another, comprising:
means for forming and planarizing a first wiring plane with interconnects and first source/drain regions of the field effect transistors;
means for forming and planarizing a first insulation layer on the planarized first wiring plane;
means for forming and planarizing a gate region layer on the first insulator layer, the gate region layer having patterned gate regions made of electrically conductive material and insulator material introduced therebetween;
means for forming and planarizing a second insulator layer on the planarized gate region layer;
means for forming a multiplicity of holes through the planarized second insulator layer, the gate regions, and the planarized first insulator layer;
means for forming at least one vertical nanoelement, which serves as a channel region, in each of the holes;
means for forming electrically insulating material as gate insulating layer between the at least one vertical nanoelement and the electrically conductive material of the gate region; and
means for forming a second wiring plane with interconnects and second source/drain regions of the field effect transistors on the planarized second insulator layer, so that each nanoelement is arranged between the first wiring plane and the second wiring plane.

23. The system of claim 22, wherein the electrically insulating material of the gate insulating layer between the respective vertical nanoelement and the respective electrically conductive material of the gate region is an oxide of the electrically conductive material of the gate region.

24. The system of claim 22, wherein the at least one nanoelement is of the n conduction type.

25. The system of claim 22, set up as a DRAM memory cell, wherein at least one of the field effect transistors is set up as a switching transistor, and
further comprising a stacked capacitor as a storage capacitor, the at least one nanoelement being grown on at least one part of the storage capacitor.

26. The system of claim 22, further comprising at least one CMOS component, wherein one field effect transistor has a nanoelement of the p conduction type and another field effect transistor has a nanoelement of the n conduction type.

27. The system of claim 26, wherein at least some of the field effect transistors are connected to form an inverter circuit.

28. The system of claim 22, further comprising additional holes formed through the planarized second insulator layer, the insulator material of the gate region layer, and the planarized first insulator layer, the additional holes being filled with an electrically conductive coupling material for electrically coupling the first wiring plane and the second wiring plane.

29. The system of claim 22, wherein the electrically insulating material surrounding the at least one vertical nanoelement is realized as a ring structure, and
wherein at least one part of the electrically insulating ring structure is surrounded by the electrically conductive material.
